(19) United States
(12) Patent Application Publication
(10) Pub. No.: US 2026/0202461 A1
(43) Pub. Date: Jul. 16, 2026

(54) SYSTEM AND METHOD OF OPERATING THE SAME

(71) Applicant: TAIWAN SEMICONDUCTOR MANUFACTURING COMPANY, LTD., Hsinchu (TW)

(72) Inventors: Yen-Jen CHEN, Hsinchu (TW); Wu-Chen LIN, Hsinchu (TW); Hsieh-Hung HSIEH, JR., Hsinchu (TW)

(21) Appl. No.: 19/188,393

(22) Filed: Apr. 24, 2025

Related U.S. Application Data
(60) Provisional application No. 63/745,584, filed on Jan. 15, 2025.

(51) Int. Cl. G01R 31/28; H01L 21/66; H03B 5/12

(52) U.S. Cl. CPC G01R 31/2831; H03B 5/1212; H10P 74/277

(57) ABSTRACT

A system includes a first circuit, a converter circuit and a testing system. The first circuit is configured to generate a radio frequency (RF) signal, the RF signal having a first oscillation frequency. The converter circuit is coupled to the first circuit, configured to receive the RF signal, and to convert the RF signal into a first voltage representative of a value of the first oscillation frequency. The first voltage is a direct current voltage. The testing system is coupled to the converter circuit, and configured to receive the first voltage, and to perform a wafer acceptance test (WAT) on the first oscillation frequency in response to the first voltage.

### PRIORITY CLAIM

This application claims the benefit of U.S. Provisional Application No. 63/745,584, filed Jan. 15, 2025, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a system, in accordance with some embodiments.

FIG. 2 is a block diagram of an integrated circuit, in accordance with some embodiments.

FIG. 3A is a circuit diagram of a VCO, in accordance with some embodiments.

FIG. 3B is a circuit diagram of a VCO, in accordance with some embodiments.

FIG. 4 illustrates a schematic drawing of an RF signal usable in FIGS. 2 and 3A-3B, in accordance with some embodiments.

FIG. 5 is a circuit diagram of an FVC circuit, in accordance with some embodiments.

FIGS. 6A-6C is a corresponding schematic diagram illustrating operation of the FVC circuit of FIG. 5, in accordance with some embodiments.

FIG. 7 illustrates a schematic drawing of oscillating signals usable in FIG. 6, in accordance with some embodiments.

FIG. 8 is a circuit diagram of an integrated circuit, in accordance with some embodiments.

FIG. 9 illustrates a schematic drawing of voltages output by the FVC circuit of FIG. 6, in accordance with some embodiments.

FIG. 10 is a circuit diagram of a frequency divider circuit, in accordance with some embodiments.

FIGS. 11A-11B is a flowchart of a method of operating a circuit, in accordance with some embodiments.

FIG. 12 is a schematic view of a system, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During the semiconductor manufacturing process, the performance of various interconnects and devices of a semiconductor wafer are evaluated by a wafer acceptance test (WAT) after the manufacturing process. Furthermore, after the semiconductor wafer is completed through semiconductor processing, a test is performed at a stage known as the wafer acceptance test.

At the wafer acceptance test, probes may be placed onto pads coupled to various devices and interconnect structures within the ICs that are formed on the semiconductor wafer, and certain measurements may be made. If the performance measured at the wafer acceptance test is not acceptable, then the semiconductor wafer, which has been processed through many processing steps, then the materials used to perform the semiconductor manufacturing process, can be wasted. At the wafer acceptance test, defect diagnosis may be implemented as part of the semiconductor manufacturing process to detect defects on the interconnect and devices of the semiconductor wafer.

Also, the wafer acceptance test can be conducted to derive the product yield. Prior to the wafer acceptance test, some test line structures (i.e. test keys and test pads) electrically connected thereto can be formed in scribe lines around the dies or non-product area of the wafer. One or more test line structures are electrically connected to an external circuit or probes of a probe card through the test pads to check the quality of the various processes in the wafer acceptance test. The wafer acceptance test can be used to confirm the stability of the semiconductor process as well as to enhance the yield of ICs. Thus, by utilizing the wafer acceptance test, the quality and the stability of the semiconductor wafers can be ensured.

In accordance with some embodiments, a system includes a wafer, and a test structure on the wafer.

In some embodiments, the test structure is configured to generate a radio frequency (RF) signal. In some embodiments, the RF signal has a first oscillation frequency.

In some embodiments, the system further includes a set of test lines coupled to the test structure. In some embodiments, the set of test lines includes a converter circuit coupled to the test structure.

In some embodiments, the converter circuit is configured to receive the RF signal. In some embodiments, the converter circuit is configured to convert the RF signal into a first voltage representative of a value of the first oscillation frequency. In some embodiments, the first voltage is a direct current voltage.

In some embodiments, the system further includes a testing system. In some embodiments, the testing system is coupled to the converter circuit. In some embodiments, the testing system is configured to receive the first voltage, and to perform a wafer acceptance test (WAT) on the first oscillation frequency in response to the first voltage.

In some embodiments, the first oscillation frequency of the test structure can reflect the capacitance variation of one or more circuit elements in the test structure. For example, in some embodiments, the test structure includes one or more voltage controlled oscillators (VCOs), and the oscillation frequency of the test structure can reflect the capacitance variation of one or more capacitors and/or metal oxide semiconducting (MOS) varactors within the test structure. In some embodiments, by utilizing the set of test lines, the capacitance variation of one or more circuit elements in the test structure can be monitored for process control, even though the test structure is configured to operate at RF, and wafer acceptance tests are not able to accurately measure RF signals compared to other approaches where WAT data is captured under DC conditions, and the WAT data is insufficient for RF performance once the circuit being tested operates at RF frequencies.

In some embodiments, by utilizing the set of test lines, the capacitance variation of one or more circuit elements in the test structure can be monitored for process control, thereby improving yield of the semiconductor wafer compared to other approaches.

In some embodiments, by utilizing the set of test lines, the capacitance variation of one or more circuit elements in the test structure can be monitored for process control, and circuit-level data with DC output is characterized compared to other approaches that cannot characterize DC output when RF circuits are utilized.

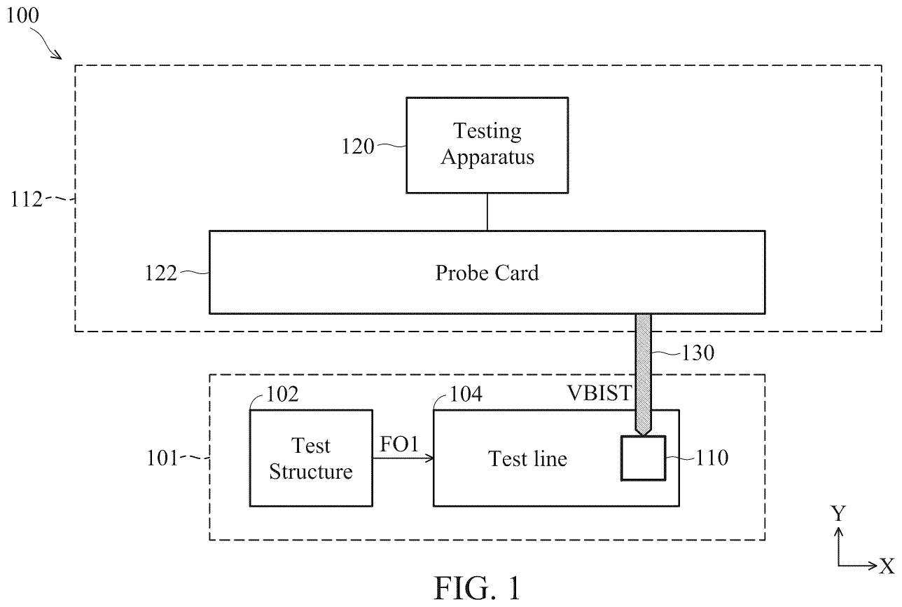

FIG. 1 is a block diagram of a system 100, in accordance with some embodiments.

FIG. 1 is simplified for the purpose of illustration. In some embodiments, system 100 includes various elements in addition to those depicted in FIG. 1 or is otherwise arranged to perform the operations discussed below.

In some embodiments, system 100 is configured to perform a wafer acceptance test (WAT) on a semiconductor wafer 101.

System 100 includes the semiconductor wafer 101 (also referred to as “wafer 101”), a test structure 102, a set of test lines 104 and a testing system 112.

In some embodiments, system 100 is configured to perform the wafer acceptance test on the test structure 102. In some embodiments, testing system 112 is configured to perform the wafer acceptance test on the test structure 102.

In some embodiments, the semiconductor wafer 101 uses various interconnect structures for interconnecting circuitry on the IC. In some embodiments, the interconnect structure includes a number of metal layers separated by one or more layers of interlayer dielectric.

In some embodiments, the test structure 102 is formed in the wafer 101. In some embodiments, the test structure 102 includes one or more circuits formed in the wafer 101. In some embodiments, the test structure 102 is configured to generate a radio frequency (RF) signal FO1. In some embodiments, the RF signal has an oscillation frequency F1.

In some embodiments, the one or more circuits that are part of the test structure 102 include one or more voltage controlled oscillators (VCOs). In some embodiments, the one or more circuits that are part of the test structure 102 include one or more LC VCOs. Other types of circuits for the test structure 102 are within the scope of the present disclosure.

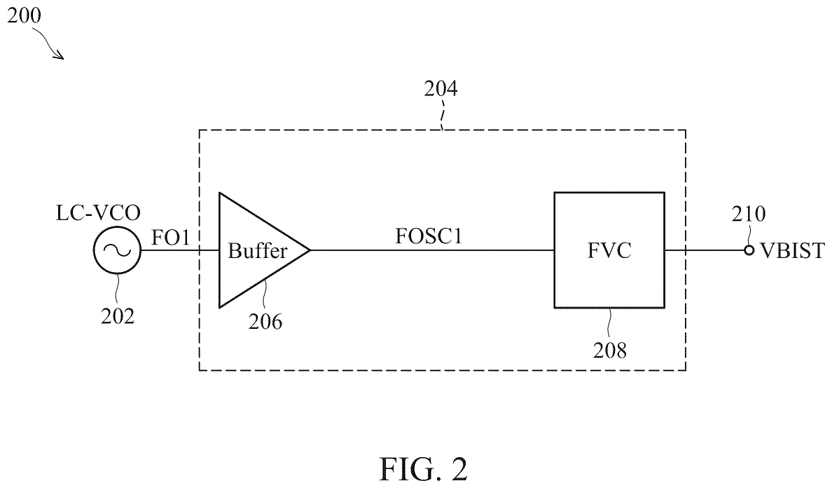

The set of test lines 104 is coupled to the test structure 102. In some embodiments, the set of test lines 104 is on the wafer 101. In some embodiments, the set of test lines 104 is configured to receive the RF signal. In some embodiments, the set of test lines 104 includes a converter circuit (e.g., converter circuit 204 of FIG. 2) configured to convert the RF signal into a voltage VBIST. In some embodiments, the voltage VBIST is representative of a value of the oscillation frequency F1. In some embodiments, the voltage VBIST is inversely related to the value of the oscillation frequency F1. For example, when the oscillation frequency F1 decreases, then the voltage VBIST increases, in accordance with some embodiments. In some embodiments, when the oscillation frequency F1 increases, then the voltage VBIST decreases.

In some embodiments, the voltage VBIST is a direct current (DC) voltage. In some embodiments, the voltage VBIST is a voltage signal with a low frequency. In some embodiments, the low frequency of the present disclosure includes frequencies ranging from about 0 Hz to about 10 megahertz (MHz). Other values or ranges for the low frequency range are within the scope of the present disclosure.

In some embodiments, one or more test line structures of the set of test lines 104 are formed on the semiconductor wafer 101. In some embodiments, the one or more test line structures of the set of test lines 104 are formed in the scribe lines (not shown) between multiple dies (not shown) of the semiconductor wafer 101. In some embodiments, the one or more test line structures of the set of test lines 104 are formed in a test range at the edge of the semiconductor wafer 101. In some embodiments, the set of test lines 104 is used for tests or other functions, as discussed below. In some embodiments, each test line structure of the set of test lines 104 includes multiple test pads, such as wafer acceptance test array pads (e.g., pad 110) and optical critical dimension (OCD) pads.

The testing system 112 is coupled to the set of test lines 104. In some embodiments, the testing system 112 is configured to receive the voltage VBIST. In some embodiments, the testing system 112 is configured to perform the wafer acceptance test on the test structure 102 by the set of test lines 104.

In some embodiments, the testing system 112 is configured to perform the wafer acceptance test on the test structure 102 by measuring the voltage VBIST, and the voltage VBIST is representative of the oscillation frequency F1 in response to the voltage VBIST, and the testing system 112 is able to indirectly analyze the oscillation frequency F1 by measuring the voltage VBIST.

In some embodiments, the oscillation frequency F1 of the test structure 102 can reflect the capacitance variation of one or more circuit elements in the test structure 102. For example, in some embodiments, the test structure 102 includes one or more VCOs, and the oscillation frequency F1 of the test structure 102 can reflect the capacitance variation of one or more capacitors and/or MOS varactors within the test structure 102. In some embodiments, by utilizing the set of test lines 104, the capacitance variation of one or more circuit elements in the test structure 102 can be monitored for process control, even though the test structure 102 is configured to operate at RF, and wafer acceptance tests are not able to accurately measure RF signals compared to other approaches where WAT data is captured under DC conditions, and the WAT data is insufficient for RF performance once the circuit being tested operates at RF frequencies.

The testing system 112 includes a testing apparatus 120, a probe card 122 and a set of probes 130. For ease of illustration, the set of probes 130 in FIG. 1 shows one probe; however, the set of probes 130 includes one or more probes.

The set of probes 130 is coupled to the set of test lines 104. The set of probes 130 is configured to receive the voltage VBIST from the set of test lines 104. In some embodiments, the set of probes 130 is coupled to the set of test lines 104 by a pad 110. In some embodiments, the pad 110 is a portion of the set of test lines 104. In some embodiments, the set of probes 130 includes one or more different types of probes 130, such as electrical probe pins, optical probes, and/or magnetic probes.

The probe card 122 is coupled to the set of probes 130. The probe card 122 is configured to receive the voltage VBIST from the set of probes 130. The probe card 122 is coupled between the set of probes 130 and the testing apparatus 120.

In some embodiments, the probe card 122 is used to perform one or more wafer acceptance tests. In some embodiments, the probe card 122 includes a number of probes (e.g., the set of probes 130).

In some embodiments, one or more probes of the set of probes 130 of the probe card 122 are in direct contact with one or more test line structures of the set of test structures 102, and the positions of the test pads of the one or more test line structures of the set of test structures 102 are identified by the probe card 122 or the testing apparatus 120.

In some embodiments, after the set of probes 130 of the probe card 122 contact the test pads of the one or more test line structures of the set of test structures 102, the probe card 122 is configured to sequentially and repeatedly apply one or more test signals to the one or more test line structures of the set of test structures 102 through the set of probes 130, and then the probe card 122 is configured to receive one or more responses from the one or more test line structures of the set of test structures 102 through the set of probes 130.

The testing apparatus 120 is coupled to the probe card 122. The testing apparatus 120 is configured to receive the voltage VBIST from the probe card 122. In some embodiments, the testing apparatus 120 is configured to measure the voltage VBIST, thereby performing the wafer acceptance test on the oscillation frequency in response to the voltage VBIST.

In some embodiments, the testing apparatus 120 is also referred to as “a tester.” In some embodiments, the testing apparatus 120 is configured to perform one or more test programs, and is configured to record one or more corresponding test results of the semiconductor wafer 101 or the test structure 102. In some embodiments, in a Back End of Line (BEOL) test, the set of test lines 104 can provide process stability on various processing parameters.

In some embodiments, the test results from the testing apparatus 120 are used to modify processing parameters for yield improvement of ICs. In some embodiments, upon the testing apparatus 120 finishing the tests, failed dies are inked and/or faulty process results are identified through the testing apparatus 120. The semiconductor wafer 101 is then diced along the scribe lines. Therefore, integrated circuit devices (chips) are created.

In some embodiments, system 100 achieves one or more of the benefits described herein.

Other configurations of system 100 are within the scope of the present disclosure.

FIG. 2 is a block diagram of an integrated circuit 200, in accordance with some embodiments.

Integrated circuit 200 is an embodiment of the test structure 102 and the set of test lines 104 of FIG. 1, and similar detailed description is therefore omitted.

Integrated circuit 200 includes a VCO 202 and a converter circuit 204.

In some embodiments, VCO 202 is an embodiment of test structure 102 of FIG. 1, and similar detailed description is therefore omitted. In some embodiments, the converter circuit 204 is an embodiment of the set of test lines 104 of FIG. 1, and similar detailed description is therefore omitted.

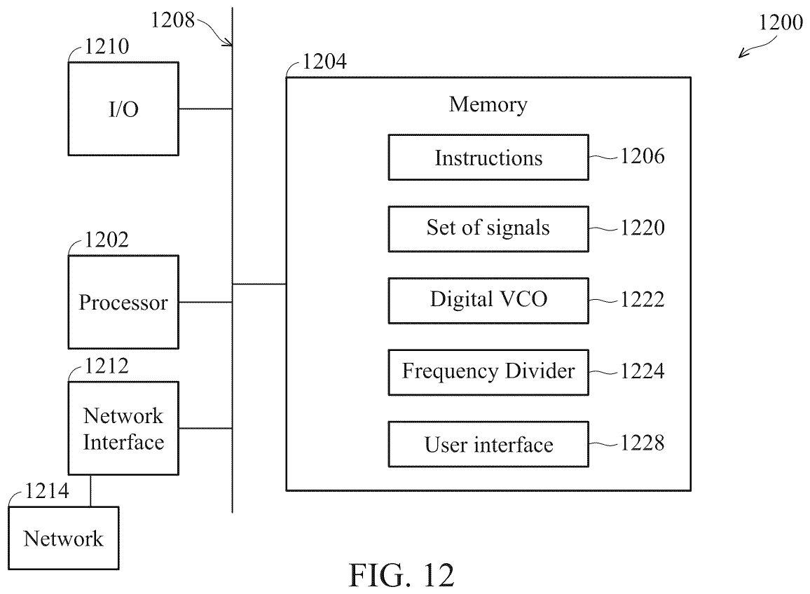

The VCO 202 is coupled to the converter circuit 204. In some embodiments, the VCO 204 is configured to receive a control signal Vctrl. In some embodiments, the VCO 204 is configured to generate the RF signal FO1 in response to the control signal Vctrl. In some embodiments, an output terminal of the VCO 202 is configured to output the RF signal FO1 to an input terminal of the converter circuit 204. The output terminal of the VCO 202 is coupled to the input terminal of the converter circuit 204. In some embodiments VCO 202 is an RF LC VCO. In some embodiments VCO 202 is a digital controlled oscillator (DCO), and a non-limiting example is shown as system 1200 in FIG. 12.

Other configurations, types or numbers of VCO 202 are within the scope of the present disclosure.

The converter circuit 204 is coupled to the VCO 202. The input terminal of the converter circuit 204 is coupled to the output terminal of the VCO 202. In some embodiments, the input terminal of the converter circuit 204 is configured to receive the RF signal FO1. The converter circuit 204 is configured to convert the RF signal FO1 into the voltage VBIST. In some embodiments, the voltage VBIST is representative of the value of the oscillation frequency F1.

In some embodiments, an output of the converter circuit 204 is configured to output the voltage VBIST on an output terminal 210. In some embodiments, the output terminal 210 is the pad 110 of FIG. 1, and similar detailed description is therefore omitted.

The converter circuit 204 includes a buffer circuit 206 and a frequency-to-voltage converter (FVC) circuit 208.

An input terminal of the buffer circuit 206 is coupled to the output terminal of the VCO 202. An output terminal of the buffer circuit 206 is coupled to an input terminal of the FVC circuit 208

The input terminal of the buffer circuit 206 is configured to receive the RF signal FO1. The output terminal of the buffer circuit 206 is configured to output an oscillating signal FOSC1 in response to the RF signal FO1. In some embodiments, the oscillating signal FOSC1 has the oscillation frequency F1. In some embodiments, the buffer circuit 206 is configured to generate the oscillating signal FOSC1 in response the RF signal FO1. In some embodiments, the oscillating signal FOSC1 is the same as the RF signal FO1.

In some embodiments, the buffer circuit 206 includes a push-pull circuit or a common-source buffer circuit. In some embodiments, the buffer circuit 206 is configured to prevent the VCO 202 from being affected by one or more elements in the converting structure 204 or one or more functions (operations) of the converting structure 204. In some embodiments buffer circuit 206 is also referred to as “a buffer amplifier circuit.”

In some embodiments, buffer circuit 206 is configured to electrically isolate the VCO 202 from one or more circuits in the converting structure 204 thereby improving the performance of the VCO 202 with frequency pulling and/or phase noise.

In some embodiments, the input terminal of the FVC circuit 208 is coupled to the output terminal of the buffer circuit 206. In some embodiments, the FVC circuit 208 is configured to receive the oscillating signal FOSC1. In some embodiments the FVC circuit 208 is configured to generate the voltage VBIST in response to the oscillating signal FOSC1.

Other configurations, types or numbers of buffer circuit 206 are within the scope of the present disclosure.

The FVC circuit 208 is coupled to the buffer circuit 206. In some embodiments the input terminal of the FVC circuit 208 is configured to receive the oscillating signal FOSC1. In some embodiments, the output terminal of the FVC circuit 208 is configured to output the voltage VBIST on the output terminal 210 of the converter circuit 204.

Other configurations, types or numbers of FVC circuit 208 are within the scope of the present disclosure.

Other configurations, types or numbers of converter circuit 204 are within the scope of the present disclosure.

In some embodiments, the oscillation frequency F1 of the VCO 202 can reflect the capacitance variation of one or more circuit elements in the VCO 202. For example, in some embodiments, the oscillation frequency F1 of the VCO 202 can reflect the capacitance variation of one or more capacitors and/or MOS varactors within the VCO 202. In some embodiments, by utilizing the converter circuit 204, the capacitance variation of one or more circuit elements in the VCO 202 can be monitored for process control compared to other approaches where WAT data is captured under DC conditions and cannot measure RF frequencies, and the WAT data is insufficient for RF performance once the circuit being tested operates at RF frequencies.

In some embodiments, by utilizing the converter circuit 204, the capacitance variation of one or more circuit elements in the VCO 202 can be monitored for process control, thereby improving yield of the semiconductor wafer compared to other approaches.

In some embodiments, by utilizing the converter circuit 204, the capacitance variation of one or more circuit elements in the VCO 202 can be monitored for process control, and circuit-level data with DC output is characterized compared to other approaches that cannot characterize DC output when RF circuits are utilized.

In some embodiments, by utilizing the FVC circuit 208, the capacitance variation of one or more circuit elements in the VCO 202 can be monitored for process control compared to other approaches where WAT data is captured under DC conditions and cannot measure RF frequencies, and the WAT data is insufficient for RF performance once the circuit being tested operates at RF frequencies.

In some embodiments, by utilizing the FVC circuit 208, the capacitance variation of one or more circuit elements in the VCO 202 can be monitored for process control, thereby improving yield of the semiconductor wafer compared to other approaches.

In some embodiments, by utilizing the FVC circuit 208, the capacitance variation of one or more circuit elements in the VCO 202 can be monitored for process control, and circuit-level data with DC output is characterized compared to other approaches that cannot characterize DC output when RF circuits are utilized.

In some embodiments, integrated circuit 200 achieves one or more of the benefits described herein.

Other configurations, types or numbers of integrated circuit 200 are within the scope of the present disclosure.

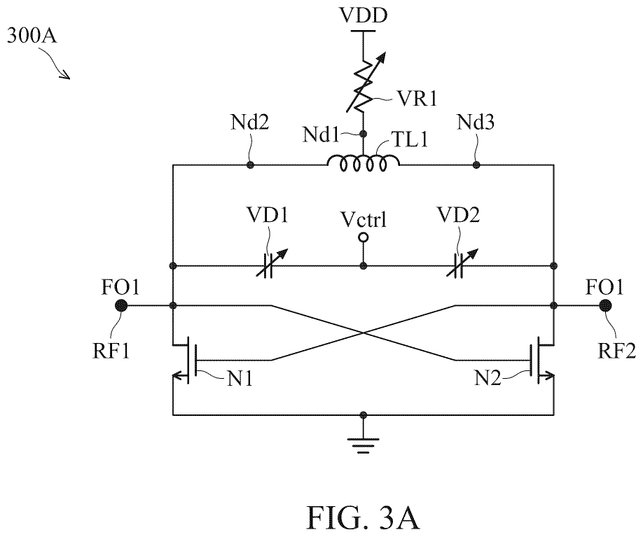

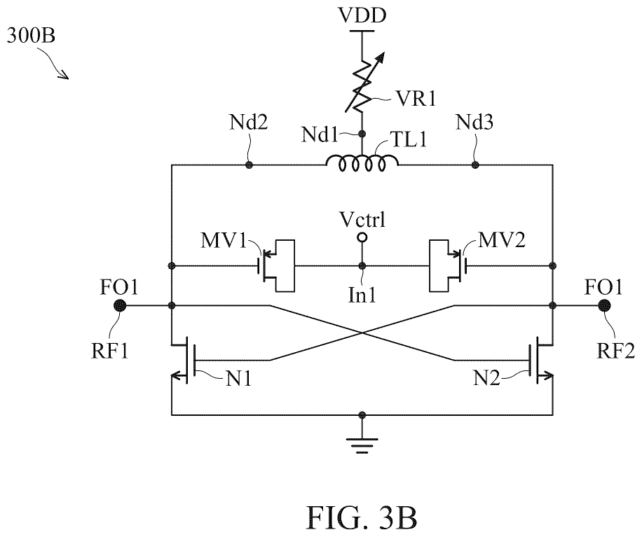

FIG. 3A is a circuit diagram of a VCO 300A, in accordance with some embodiments.

VCO 300A is an embodiment of VCO 202 of FIG. 2, and similar detailed description is therefore omitted.

VCO 300A includes a variable resistor VR1, an inductor TL1, a varactor VD1, a varactor VD2, and an N-type Metal Oxide Semiconductor (NMOS) transistor N1 and an NMOS transistor N2.

The variable resistor VR1 is coupled between a voltage supply VDD and a node Nd1. In some embodiments, the variable resistor VR1 is configured to adjust the resistance of the VCO 300A.

Other types, configurations or numbers of inductors for variable resistor VR1 are within the scope of the present disclosure.

The inductor TL1 is coupled between a node Nd1, a node ND2 and a node Nd3. The inductor TL1 is coupled to the variable resistor VR1 by node Nd1.

The inductor TL1 includes a first terminal, a second terminal and a third terminal. The first terminal of the inductor TL1 is coupled to the variable resistor VR1 and the node Nd1. The second terminal of the inductor TL1 is coupled to at least the node ND2. The third terminal of the inductor TL1 is coupled to at least the node Nd3.

In some embodiments, the inductor TL1 is a tapped inductor. In some embodiments, the inductor TL1 is a variable inductor where the inductance can be adjusted.

Other types, configurations or numbers of inductors for inductor TL1 are within the scope of the present disclosure.

The varactor VD1 includes a first terminal and a second terminal. The first terminal of varactor VD1 is coupled to the node Nd2 and the second terminal of the inductor TL1. The second terminal of the first varactor coupled to an input node In1.

In some embodiments, varactor VD1 is a varactor diode. In some embodiments, varactor VD1 is a MOS varactor, such as MOS varactor MV1 in FIG. 3A, and similar detailed description is therefore omitted.

The varactor VD2 includes a first terminal and a second terminal. The first terminal of the varactor VD2 is coupled to the node Nd3 and the third terminal of the inductor TL1. The second terminal of the varactor VD2 is coupled to the input node In1 and the second terminal of the varactor VD1. In some embodiments, the input node In1 is configured to receive a control signal Vctrl.

In some embodiments, the control signal Vctrl is configured to adjust the oscillation frequency (e.g., oscillation frequency F1) of the output signal of the VCO 300A. In some embodiments, the control signal Vctrl is configured to adjust the oscillation frequency (e.g., oscillation frequency F1) of the output signal of the VCO 300A by adjusting the capacitance of the varactors VD1 and VD2. In some embodiments, increasing the control signal Vctrl causes the oscillation frequency F1 of the RF signal FO1 output by the VCO 300A to increase. In some embodiments, decreasing the control signal Vctrl causes the oscillation frequency F1 of the signal FO1 output by the VCO 300A to decrease.

Other types, configurations or numbers of varactors for varactor VD1 and/or VD2 are within the scope of the present disclosure.

NMOS transistor N1 and NMOS transistor N2 are coupled to each other in a cross coupled manner.

In some embodiments, each of the gate terminal of the NMOS transistor N1, the drain/source terminal of the NMOS transistor N2, the first terminal of the varactor VD2, the node Nd3 and the third terminal of the inductor VD1 are coupled together, and correspond to an output terminal RF2 of the VCO 300A.

In some embodiments, each of the gate terminal of the NMOS transistor N2, the drain/source terminal of the NMOS transistor N1, the first terminal of the varactor VD1, the node Nd2 and the second terminal of the inductor L1 are coupled together, and correspond to an output terminal RF1 of the VCO 300A. In some embodiments, the output terminals RF1 and RF2 of the VCO 300A is configured to output the RF signal FO1.

In some embodiments, each of the source/drain terminal of the NMOS transistor N1 and the source/drain terminal of the NMOS transistor N2 is coupled to a reference voltage supply VSS.

Other transistor types are within the scope of the present disclosure. In some embodiments, at least one of NMOS transistors N1 or N2 is a corresponding n-type transistor. In some embodiments, at least one of NMOS transistors N1 or N2 is a corresponding p-type transistor.

In some embodiments, at least one of NMOS transistors N1 or N2 is a corresponding P-type Metal Oxide Semiconductor (PMOS) transistor.

Other types, configurations or numbers of transistors for NMOS transistor N1 are within the scope of the present disclosure.

Other types, configurations or numbers of transistors for NMOS transistor N2 are within the scope of the present disclosure.

In some embodiments, VCO 300A achieves one or more of the benefits described herein.

Other configurations, types or numbers of circuit elements in VCO 300A are within the scope of the present disclosure.

FIG. 3B is a circuit diagram of a VCO 300B, in accordance with some embodiments.

VCO 300B is an embodiment of VCO 202 of FIG. 2, and similar detailed description is therefore omitted.

VCO 300B is a variation of VCO 300A of FIG. 3A, and similar detailed description is therefore omitted. In comparison with VCO 300A of FIG. 3A, varactor VD1 of FIG. 3A is replaced with a MOS varactor MV1, and varactor VD2 of FIG. 3A is replaced with a MOS varactor MV2, and similar detailed description is therefore omitted.

VCO 300B includes the variable resistor VR1, the inductor TL1, the MOS varactor MV1, the MOS varactor MV2, NMOS transistor N1 and NMOS transistor N2.

In some embodiments, the MOS varactor MV1 is a PMOS varactor diode. In some embodiments, the MOS varactor MV2 is a PMOS varactor diode.

The MOS varactor MV1 includes a gate terminal, a drain terminal and a source terminal. In some embodiments, each of the gate terminal of MOS varactor MV1, the gate terminal of the NMOS transistor N2, the drain/source terminal of the NMOS transistor N1, the node Nd2 and the second terminal of the inductor L1 are coupled together, and correspond to an output terminal RF1 of the VCO 300B.

The MOS varactor MV2 includes a gate terminal, a drain terminal and a source terminal. In some embodiments, each of the gate terminal of MOS varactor MV2, the gate terminal of the NMOS transistor N1, the drain/source terminal of the NMOS transistor N2, the node Nd3 and the third terminal of the inductor VD1 are coupled together, and correspond to an output terminal RF2 of the VCO 300B. In some embodiments, the output terminals RF1 and RF2 of the VCO 300B is configured to output the RF signal FO1.

Other transistor types are within the scope of the present disclosure. In some embodiments, at least one of MOS varactors MV1 or MV2 is a corresponding NMOS varactor.

Other types, configurations or numbers of transistors for MOS varactor MV1 are within the scope of the present disclosure.

Other types, configurations or numbers of transistors for MOS varactor MV2 are within the scope of the present disclosure.

In some embodiments, VCO 300B achieves one or more of the benefits described herein.

Other configurations, types or numbers of circuit elements in VCO 300B are within the scope of the present disclosure.

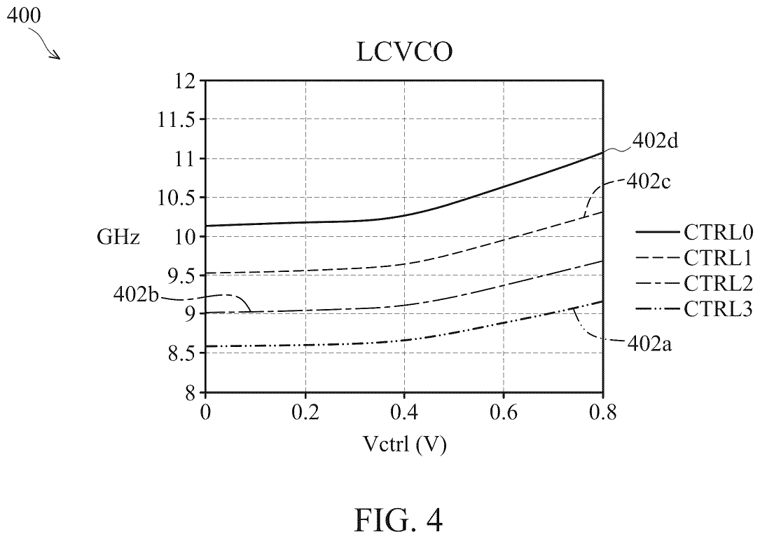

FIG. 4 illustrates a schematic drawing 400 of an RF signal usable in FIGS. 2 and 3A-3B, in accordance with some embodiments.

In some embodiments, the RF signal of FIG. 4 is the RF signal FO1 of FIGS. 2 and 3A-3B, in accordance with some embodiments.

Schematic drawing 400 of FIG. 4 includes a horizontal axis and a vertical axis. As shown in FIG. 4, the horizontal axis shows a range of voltages for the control signal Vctrl input to the VCO 300A or 300B, and the vertical axis shows a range of frequencies for the RF signal FO1 for VCO 202, VCO 300A and VCO 300B. In some embodiments, the range of frequencies for the RF signal FO1 has the units of gigahertz (GHz).

As shown in FIG. 4, schematic drawing 400 shows frequency characteristics for the RF signal FO1 output by VCO 300A or VCO 300B, over a range of voltages Vctrl provided to input node In1 of VCO 300A and VCO 300B.

Schematic drawing 400 includes curves 402a, 402b, 402c and 402d for different control voltages that are provided to a capacitive array (not shown).

In some embodiments, increasing the control signal Vctrl causes the oscillation frequency F1 of the RF signal FO1 output by VCO 300A or 300B to increase. In some embodiments, decreasing the control signal Vctrl causes the oscillation frequency F1 of the signal FO1 output by the VCO 300A or 300B to decrease.

Other configurations or numbers of curves in schematic drawing 400 are within the scope of the present disclosure.

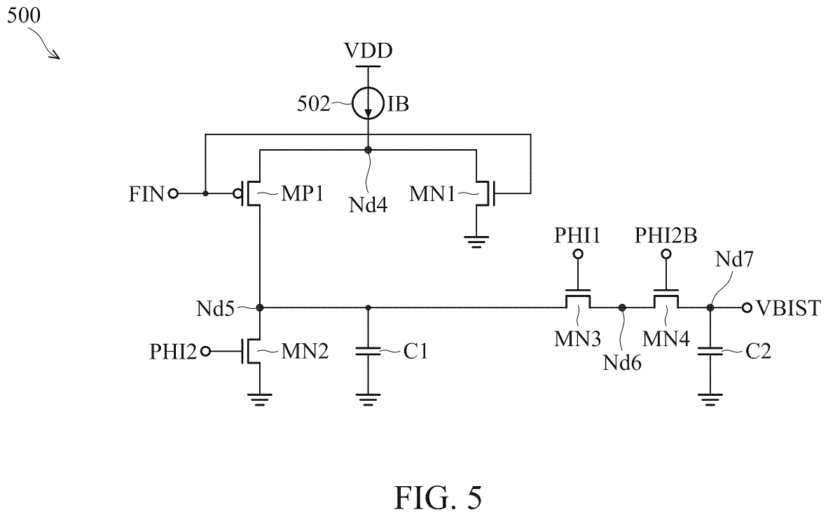

FIG. 5 is a circuit diagram of an FVC circuit 500, in accordance with some embodiments.

FVC circuit 500 is an embodiment of FVC circuit 208 of FIG. 2, and similar detailed description is therefore omitted.

FVC circuit 500 includes a current source 502, a PMOS transistor MP1, an NMOS transistor MN1, an NMOS transistor MN2, an NMOS transistor MN3, an NMOS transistor MN4, a capacitor C1 and a capacitor C2.

The current source 502 is coupled between a voltage supply VDD and a node Nd4. In some embodiments, the current source 502 is configured to generate a current IB. In some embodiments, the current source 502 is configured to adjust the current IB of the FVC circuit 500.

Other types, configurations or numbers of current source 502 are within the scope of the present disclosure.

A gate terminal of the PMOS transistor MP1 is configured to receive the oscillating signal FIN. A source/drain of the first PMOS transistor MP1 is coupled to at least the node Nd4 and the current source 502. A drain/source of the PMOS transistor MP1 is coupled to at least a node Nd5.

A gate terminal of the NMOS transistor MN1 is configured to receive the oscillating signal FIN. Each of the gate terminal of the NMOS transistor MN1 and the gate terminal of the PMOS transistor MP1 are coupled together. A source/drain terminal of the NMOS transistor MN1 is coupled to a reference voltage supply VSS.

Each of a drain/source terminal of the NMOS transistor MN1, a source/drain terminal of the PMOS transistor MP1 and the current source 502 are coupled together at node Nd4.

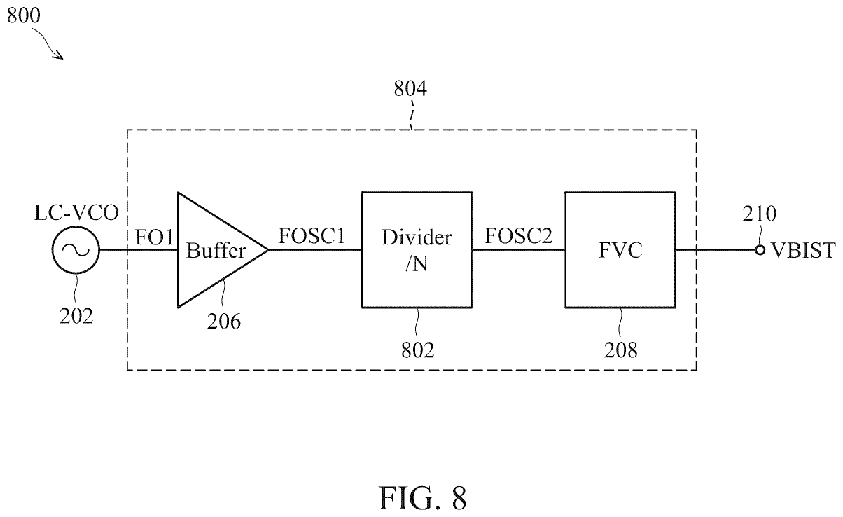

In some embodiments, the oscillating signal FIN includes one of the oscillating signal FOSC1 or the oscillating signal FOSC2. For example, in some embodiments, when the FVC circuit 500 is usable as the FVC circuit 208 of FIG. 2, then the oscillating signal FIN is the oscillating signal FOSC1, and similar detailed description is omitted. For example, in some embodiments, when the FVC circuit 500 is usable as the FVC circuit 208 of FIG. 8, then the oscillating signal FIN is the oscillating signal FOSC2, and similar detailed description is omitted.

A gate terminal of the NMOS transistor MN2 is configured to receive a phase signal PHI2. In some embodiments, the phase signal PHI2 is generated by an external circuit. In some embodiments, the phase signal PHI 2 is generated by testing apparatus 120. In some embodiments, the phase signal PHI 2 is generated by a system, such as system 1200 of FIG. 12.

A source/drain terminal of the NMOS transistor MN2 is coupled to the reference voltage supply VSS.

Each of a drain/source terminal of the NMOS transistor MN2, the drain/source terminal of the PMOS transistor MP1, the node Nd5, a first end of capacitor C1 and a source/drain terminal of the NMOS transistor MN3 are coupled together.

The capacitor C1 is coupled between the reference voltage supply VSS and node Nd5. A second end of the capacitor C1 is coupled to the reference voltage supply VSS.

A gate terminal of the NMOS transistor MN3 is configured to receive a phase signal PHI1. In some embodiments, the phase signal PH1 is generated by an external circuit. In some embodiments, the phase signal PHI1 is generated by testing apparatus 120. In some embodiments, the phase signal PHI1 is generated by a system, such as system 1200 of FIG. 12.

Each of a drain/source terminal of the NMOS transistor MN3, a source/drain terminal of the NMOS transistor MN4 and a node Nd6 are coupled together.

A gate terminal of the fourth NMOS transistor MN4 is configured to receive a phase signal PHI2B. In some embodiments, the phase signal PHI2B is inverted from the phase signal PHI2, and vice versa. A drain/source terminal of the fourth NMOS transistor MN4 is coupled to an output node Nd7 and a first end of capacitor C2.

The capacitor C2 is coupled between the reference voltage supply VSS and the output node Nd7. A second end of the capacitor C2 is coupled to the reference voltage supply VSS.

In some embodiments, at least one of the drain/source terminal of the fourth NMOS transistor MN4 or the capacitor C2 is configured to output the voltage VBIST.

Other types, configurations or numbers of capacitors for at least capacitor C1 or C2 are within the scope of the present disclosure. In some embodiments, at least one of capacitor C1 or C2 is a PMOS or NMOS coupled transistor.

Other types, configurations or numbers of transistors for PMOS transistor MP1 are within the scope of the present disclosure. In some embodiments, PMOS transistor MP1 is a corresponding p-type transistor. In some embodiments, PMOS transistor MP1 is a corresponding n-type transistor. In some embodiments, PMOS transistor MP1 is a corresponding NMOS transistor.

Other types, configurations or numbers of transistors for one or more of NMOS transistors MN2, MN3 or MN4 are within the scope of the present disclosure. In some embodiments, at least one of NMOS transistors MN1, MN2 or MN3 is a corresponding n-type transistor. In some embodiments, at least one of NMOS transistors MN1, MN2 or MN3 is a corresponding p-type transistor. In some embodiments, at least one of NMOS transistors MN1, MN2 or MN3 is a corresponding PMOS transistor.

In some embodiments, the oscillation frequency F1 of at least one of VCO 202, 300A or 300B can reflect the capacitance variation of one or more circuit elements in at least one of VCO 202, 300A or 300B. For example, in some embodiments, the oscillation frequency F1 of at least one of VCO 202, 300A or 300B can reflect the capacitance variation of one or more capacitors and/or MOS varactors within at least one of VCO 202, 300A or 300B. In some embodiments, by utilizing the FVC circuit 500, the capacitance variation of one or more circuit elements in at least one of VCO 202, 300A or 300B can be monitored for process control compared to other approaches where WAT data is captured under DC conditions and cannot measure RF frequencies, and the WAT data is insufficient for RF performance once the circuit being tested operates at RF frequencies.

In some embodiments, by utilizing the FVC circuit 500, the capacitance variation of one or more circuit elements in at least one of VCO 202, 300A or 300B can be monitored for process control, thereby improving yield of the semiconductor wafer compared to other approaches.

In some embodiments, by utilizing the FVC circuit 500, the capacitance variation of one or more circuit elements in at least one of VCO 202, 300A or 300B can be monitored for process control, and circuit-level data with DC output is characterized compared to other approaches that cannot characterize DC output when RF circuits are utilized.

In some embodiments, the FVC circuit 500 of schematic diagram 600A, 600B or 600C achieves one or more of the benefits described herein.

Other configurations, types or numbers of circuit elements in FVC circuit 500 are within the scope of the present disclosure.

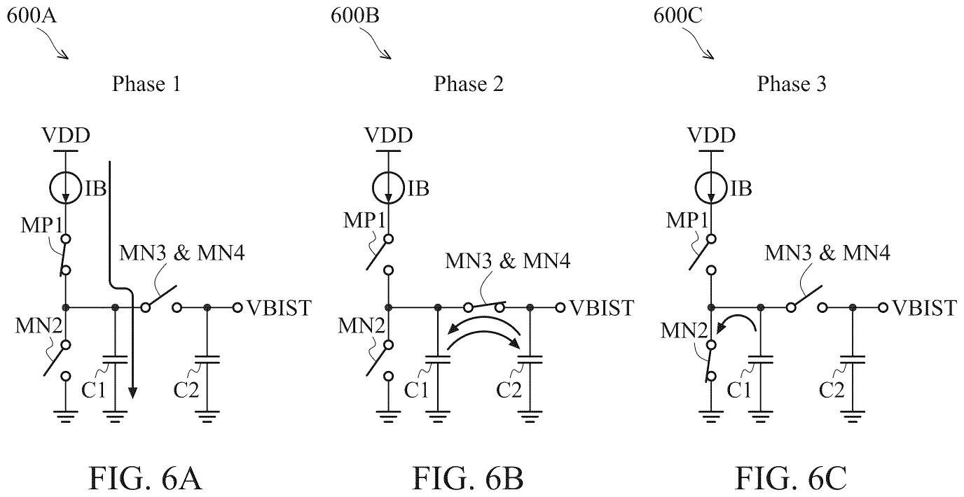

FIGS. 6A-6C is a corresponding schematic diagram 600A-600C illustrating operation of the FVC circuit 500 of FIG. 5, in accordance with some embodiments.

In some embodiments, the operation of the FVC circuit 500 is divided into three phases and is shown by schematic diagrams 600A-600C.

Schematic diagram 600A is a non-limiting example of a first phase (also referred to as “phase 1”) of operating the FVC circuit 500, and similar detailed description is therefore omitted.

In some embodiments, phase 1 shown in schematic diagram 600A includes charging capacitor C1 in response to PMOS transistor MP1 turning on, and NMOS transistor MN2, NMOS transistor MN3 and NMOS transistor MN4 turning off.

In some embodiments, the PMOS transistor MP1 is turned on in response to the oscillating signal FIN. In some embodiments, the NMOS transistor MN2, the NMOS transistor MN3 and the NMOS transistor MN4 are turned off in response to corresponding phase signal PHI2, phase signal PHI1 and phase signal PHI2B.

Schematic diagram 600B is a non-limiting example of a second phase (also referred to as “phase 2”) of operating the FVC circuit 500, and similar detailed description is therefore omitted.

In some embodiments, phase 2 shown in schematic diagram 600B includes charging capacitor C2 thereby setting the voltage VBIST in response to NMOS transistor MN3 and NMOS transistor MN4 turning on, and PMOS transistor MP1 and NMOS transistor MN1 turning off.

In some embodiments, the PMOS transistor MP1 is turned off in response to the oscillating signal FIN. In some embodiments, the NMOS transistor MN2 is turned off in response to the phase signal PHI2. In some embodiments, the NMOS transistor MN3 and the NMOS transistor MN4 are turned off in response to the corresponding phase signal PHI1 and the phase signal PHI2B.

In some embodiments, since the capacitor C1 is charged in phase 1, and since NMOS transistor MN3 and NMOS transistor MN4 are turned on for phase 2 of schematic diagram 600B, then capacitor C2 is charged by capacitor C1, and the voltage VBIST is set by capacitor C2.

Schematic diagram 600C is a non-limiting example of a second phase (also referred to as “phase 3”) of operating the FVC circuit 500, and similar detailed description is therefore omitted.

In some embodiments, phase 3 shown in schematic diagram 600C includes discharging capacitor C1 in response to NMOS transistor MN2 turning on, and PMOS transistor MP1, NMOS transistor MN3 and NMOS transistor MN4 turning off.

In some embodiments, the PMOS transistor MP1 turns off in response to the oscillating signal FIN. In some embodiments, the NMOS transistor MN2 turns on in response to the phase signal PHI2. In some embodiments, the NMOS transistor MN3 and the NMOS transistor MN4 turn off in response to the corresponding phase signal PHI1 and the phase signal PHI2B.

In some embodiments, since NMOS transistor MN3 and NMOS transistor MN4 are turned off for phase 3 of schematic diagram 600C, and since NMOS transistor MN2 is turned on, then capacitor C1 is discharged through NMOS transistor MN2 to ground (e.g., reference voltage supply VSS).

In some embodiments, the FVC circuit 500 of schematic diagram 600A, 600B or 600C achieves one or more of the benefits described herein.

Other configurations, types or numbers of circuit elements in one or more of schematic diagram 600A, 600B or 600C are within the scope of the present disclosure.

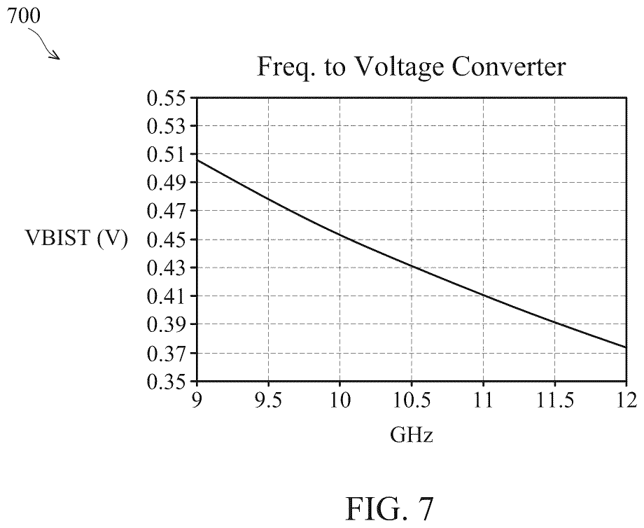

FIG. 7 illustrates a schematic drawing 700 of oscillating signals usable in FIG. 6, in accordance with some embodiments.

In some embodiments, the oscillating signals FIN of FIG. 7 is the oscillating signal FOSC1 of FIG. 2 or the oscillating signal FOSC2 of FIG. 8, in accordance with some embodiments.

Schematic drawing 700 of FIG. 7 includes a horizontal axis and a vertical axis. As shown in FIG. 7, the horizontal axis shows a range of frequencies for the oscillating signal FIN received by the FVC circuit 500, and the vertical axis shows a range of voltages for the voltage VBIST output by the FVC circuit 500.

In some embodiments, the range of frequencies for the oscillating signal FIN has the units of gigahertz (GHz). In some embodiments, the range of voltages for the voltage VBIST has the units of volts (V).

As shown in FIG. 7, schematic drawing 700 shows voltage characteristics for the voltage VBIST over a range of frequencies for the oscillating signal FIN, and similar detailed description is therefore omitted.

Schematic drawing 700 includes a curve 702a for voltage VBIST for a range of various frequencies for the oscillating signal FIN. In some embodiments, the frequency of the oscillating signal FIN is inversely related to the voltage VBIST. In some embodiments, increasing the frequency of the oscillating signal FIN causes the voltage VBIST to decrease. In some embodiments, decreasing the frequency of the oscillating signal FIN causes the voltage VBIST to increase.

Other configurations or numbers of curves in schematic drawing 700 are within the scope of the present disclosure.

FIG. 8 is a circuit diagram of an integrated circuit 800, in accordance with some embodiments.

Integrated circuit 800 is an embodiment of the test structure 102 and the set of test lines 104 of FIG. 1, and similar detailed description is therefore omitted.

Integrated circuit 800 is a variation of integrated circuit 200 of FIG. 2, and similar detailed description is therefore omitted. In comparison with integrated circuit 200 of FIG. 2, a converter circuit 804 replaces converter circuit 204 of FIG. 2, and similar detailed description is therefore omitted.

Integrated circuit 800 includes the VCO 202 coupled to converter circuit 804.

Converter circuit 804 is a variation of converter circuit 204 of FIG. 2, and similar detailed description is therefore omitted. In comparison with converter circuit 204 of FIG. 2, converter circuit 804 further includes a frequency divider circuit 802, and similar detailed description is therefore omitted. For example, by including the frequency divider circuit 802, the converter circuit 804 is configured to reduce the oscillation frequency of the oscillating signal FOSC1, thereby configuring the FVC circuit 208 to operate on oscillating signals with a lower oscillation frequency.

The converter circuit 804 is coupled to the VCO 202. The input terminal of the converter circuit 804 is coupled to the output terminal of the VCO 202. In some embodiments, the input terminal of the converter circuit 804 is configured to receive the RF signal FO1. The converter circuit 804 is configured to convert the RF signal FO1 into the voltage VBIST. In some embodiments, the voltage VBIST is representative of the value of the oscillation frequency F1.

In some embodiments, an output of the converter circuit 804 is configured to output the voltage VBIST on an output terminal 210. In some embodiments, the output terminal 210 is the pad 110 of FIG. 1, and similar detailed description is therefore omitted.

The converter circuit 804 includes the buffer circuit 206, a frequency divider circuit 802 and the FVC circuit 208.

An output terminal of the buffer circuit 206 is coupled to an input terminal of the frequency divider circuit 802. The output terminal of the buffer circuit 206 is configured to output an oscillating signal FOSC1 in response to the RF signal FO1. The output terminal of the buffer circuit 206 is configured to output the oscillating signal FOSC1 to the input terminal of the frequency divider circuit 802.

Other configurations, types or numbers of buffer circuit 206 are within the scope of the present disclosure.

The frequency divider circuit 802 is between buffer circuit 206 and FVC circuit 208.

The frequency divider circuit 802 is configured to receive the oscillating signal FOSC1. The frequency divider circuit 802 is configured to generate an oscillating signal FOSC2 in response to the oscillating signal FOSC1. In some embodiments, the oscillating signal FOSC2 has an oscillating frequency F2 less than the oscillating frequency F1.

In some embodiments, the oscillation frequency F2 of the oscillating signal FOSC2 is equal to the oscillation frequency F1 of the oscillating signal FOSC1 divided by a scaling factor N, where N is an integer. In some embodiments, the relationship between the oscillation frequency F2 and the oscillation frequency F1 is expressed as formula 1 as:

$$F 2 = F 1 / N \qquad ( 1 )$$

The oscillation frequency F2 is less than the oscillation frequency F1. In some embodiments, the oscillation frequency F2 is greater than or equal to the oscillation frequency F1.

The input terminal of the frequency divider circuit 802 is configured to receive the oscillating signal FOSC1 from the buffer circuit 206. In some embodiments, an output terminal of the frequency divider circuit 802 is coupled to the input terminal of the FVC circuit 208. In some embodiments, the output terminal of the frequency divider circuit 802 is configured to output the oscillating signal FOSC2 to the input terminal of the FVC circuit 208.

In some embodiments, the frequency divider circuit 802 is one or more flip-flops connected as a frequency division divide-by-M counter circuit, where M is an integer and the frequency of the frequency divider circuit 802 is divided by M.

In some embodiments, the frequency divider circuit 802 is one or more true-single-phase-clock (TSPC) or current-mode-logic (CML) frequency dividers.

In some embodiments, the frequency divider circuit 802 is one or more digital frequency dividers, such as system 1200 of FIG. 12.

Other configurations, types or numbers of frequency divider circuit 802 are within the scope of the present disclosure.

In some embodiments, the input terminal of the FVC circuit 208 is coupled to the output terminal of the frequency divider circuit 802. In some embodiments, the FVC circuit 208 is configured to receive the oscillating signal FOSC2. In some embodiments the FVC circuit 208 is configured to generate the voltage VBIST in response to the oscillating signal FOSC2.

The FVC circuit 208 is coupled to the frequency divider circuit 802. In some embodiments the input terminal of the FVC circuit 208 is configured to receive the oscillating signal FOSC2. In some embodiments, the output terminal of the FVC circuit 208 is configured to output the voltage VBIST on the output terminal 210 of the converter circuit 804.

Other configurations, types or numbers of FVC circuit 208 are within the scope of the present disclosure.

Other configurations, types or numbers of converter circuit 804 are within the scope of the present disclosure.

In some embodiments, the oscillation frequency F1 of the VCO 202 can reflect the capacitance variation of one or more circuit elements in the VCO 202. For example, in some embodiments, the oscillation frequency F1 of the VCO 202 can reflect the capacitance variation of one or more capacitors and/or MOS varactors within the VCO 202. In some embodiments, by utilizing the converter circuit 804, the capacitance variation of one or more circuit elements in the VCO 202 can be monitored for process control compared to other approaches where WAT data is captured under DC conditions and cannot measure RF frequencies, and the WAT data is insufficient for RF performance once the circuit being tested operates at RF frequencies.

In some embodiments, by utilizing the converter circuit 804, the capacitance variation of one or more circuit elements in the VCO 202 can be monitored for process control, thereby improving yield of the semiconductor wafer compared to other approaches.

In some embodiments, by utilizing the converter circuit 804, the capacitance variation of one or more circuit elements in the VCO 202 can be monitored for process control, and circuit-level data with DC output is characterized compared to other approaches that cannot characterize DC output when RF circuits are utilized.

In some embodiments, integrated circuit 800 achieves one or more of the benefits described herein.

Other configurations, types or numbers of integrated circuit 800 are within the scope of the present disclosure.

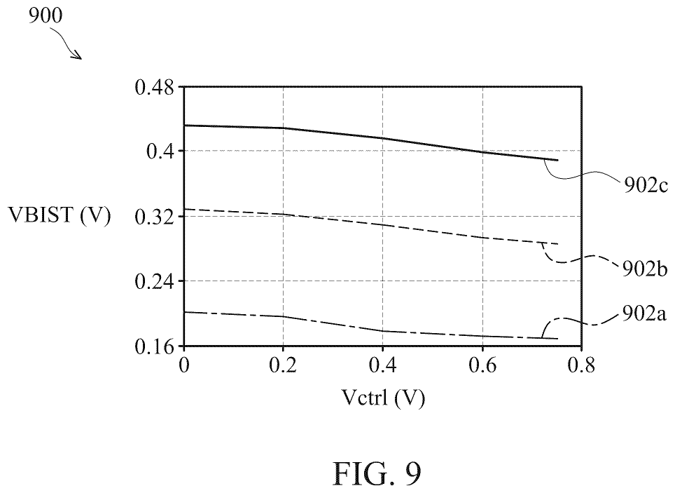

FIG. 9 illustrates a schematic drawing 900 of voltages output by the FVC circuit 600 of FIG. 6, in accordance with some embodiments.

In some embodiments, the voltages output by the FVC circuit 600 of FIG. 6 include the voltage VBIST, in accordance with some embodiments.

Schematic drawing 900 of FIG. 9 includes a horizontal axis and a vertical axis. As shown in FIG. 9, the horizontal axis shows a range of voltages Vctrl provided to the input node In1 of VCO 300A and VCO 300B, and the vertical axis shows a range of voltages for the voltage VBIST output by the FVC circuit 500.

In some embodiments, the range of voltages for the voltage Vctrl has the units of volts (V), and the range of voltages for the voltage VBIST has the units of volts (V).

As shown in FIG. 9, schematic drawing 900 shows voltage characteristics for the voltage VBIST over a range of voltages for the voltage Vctrl, and similar detailed description is therefore omitted.

Schematic drawing 900 includes curve 702a, 702b and 702c for the corresponding voltage VBIST for a range of various voltages for the voltage Vctrl. In some embodiments, the curves 702a, 702b and 702c are the output curves of different corresponding FVC circuits on different corresponding portions of the wafer 101.

In some embodiments, the voltage VBIST is inversely related to the voltage Vctrl. In some embodiments, increasing the voltage Vctrl causes the voltage VBIST to decrease. In some embodiments, decreasing the voltage Vctrl causes the voltage VBIST to increase.

Other configurations or numbers of curves in schematic drawing 900 are within the scope of the present disclosure.

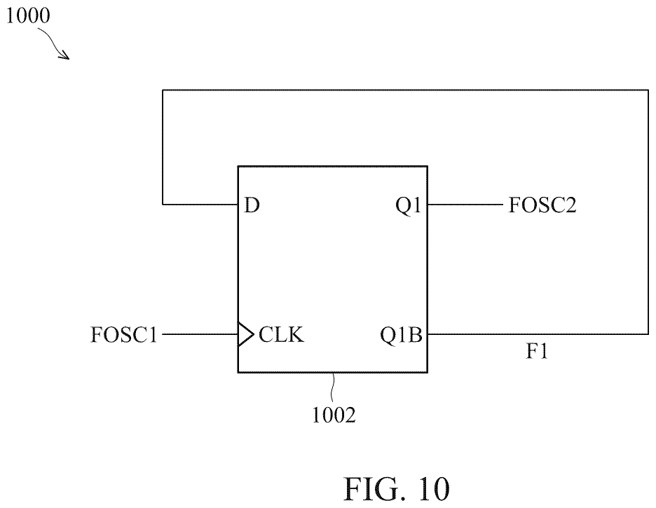

FIG. 10 is a circuit diagram of a frequency divider circuit 1000, in accordance with some embodiments.

Frequency divider circuit 1000 is an embodiment of frequency divider circuit 802 of FIG. 8, and similar detailed description is therefore omitted.

Frequency divider circuit 1000 includes a flip-flop 1002.

Frequency divider circuit 1000 is a frequency division divide-by-2 counter circuit.

Flip-flop 1002 is a 1 bit flip-flop. Other numbers of bits or numbers of corresponding flip-flops in frequency divider circuit 1000 are within the scope of the present disclosure.

Flip-flop 1002 is a DQ flip-flop. In some embodiments, flip-flop 1002 includes an SR-flip-flop, a T flip-flop, a JK flip-flop, or the like. Other types of flip-flops or configurations for flip-flop 1002 is within the scope of the present disclosure.

Flip-flop 1002 includes a clock input terminal CLK configured to receive the oscillating signal FOSC1.

Flip-flop 1002 further includes an output terminal Q1 configured to output the oscillating signal FOSC2.

Flip-flop 1002 further includes an inverted output terminal Q1B and a data input terminal D. The inverted output terminal Q1B is coupled to a data input terminal D. In some embodiments, the inverted output terminal Q1B is configured to output an inverted version of the oscillating signal FOSC2 to the data input terminal D. In some embodiments, the data input terminal D is configured to receive the inverted version of the oscillating signal FOSC2.

Other types, configurations or numbers of flip-flops are within the scope of the present disclosure.

In some embodiments, the frequency divider circuit 1000 achieves one or more of the benefits described herein.

Other configurations, types or numbers of circuit elements in frequency divider circuit 1000 are within the scope of the present disclosure.

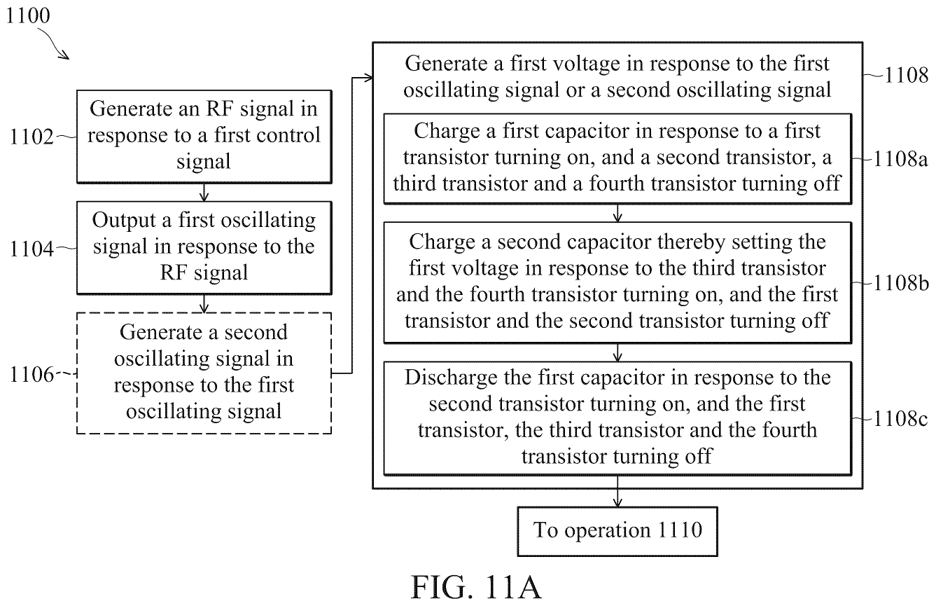

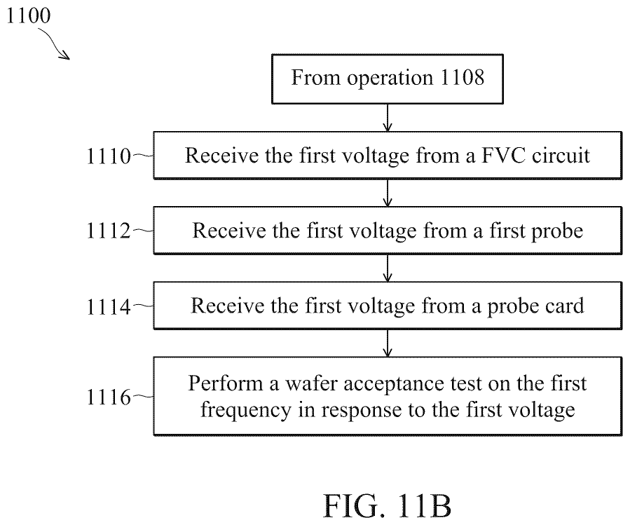

FIGS. 11A-11B is a flowchart of a method 1100 of operating a circuit, in accordance with some embodiments.

In some embodiments, FIGS. 11A-11B are flowcharts of a method 1100 of operating at least one of system 100 of FIG. 1, and similar detailed description is omitted for brevity.

In some embodiments, FIGS. 11A-11B are flowcharts of a method 1100 of operating at least one of test structure 102, set of test lines 104, 204 or 804, probe card 122, set of probes 130, testing apparatus 120, integrated circuit 200 or 800, VCO 300A or 300B, FVC circuit 500, frequency divider circuit 1000 or system 1200, and similar detailed description is omitted for brevity.

In some embodiments, FIGS. 11A-11B are flowcharts of a method 1100 of operating a system, and the method 1100 includes the features of at least one of schematic drawing 400 of FIG. 4, schematic diagram 600A of FIG. 6A, schematic diagram 600B of FIG. 6B, schematic diagram 600C of FIG. 6C, schematic drawing 700 of FIG. 7, schematic drawing 900 of FIG. 9, and similar detailed description is omitted for brevity.

It is understood that additional operations may be performed before, during, and/or after the method 1100 depicted in FIGS. 11A-11B, and that some other operations may only be briefly described herein. It is understood that method 1100 utilizes features of one or more of at least one of system 100 of FIG. 1, integrated circuit 200 of FIG. 2, VCO 300A of FIG. 3A, VCO 300B of FIG. 3A, FVC circuit 500 of FIG. 5, integrated circuit 800 of FIG. 8, frequency divider circuit 1000 of FIG. 10 or system 1200 of FIG. 12, and similar detailed description is omitted for brevity.

In some embodiments, other order of operations of method 1100 is within the scope of the present disclosure. Method 1100 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 1100 is not performed.

In operation 1102 of method 1100, an RF signal is generated in response to a first control signal.

In some embodiments, the RF signal is generated by a first circuit.

In some embodiments, the RF signal of method 1100 includes RF signal FO1.

In some embodiments, the RF signal has a first oscillation frequency. In some embodiments, the first oscillation frequency of method 1100 includes oscillation frequency F1.

In some embodiments, the first circuit of method 1100 includes at least one of test structure 102, VCO 202, VCO 300A or VCO 300B.

In some embodiments, the first control signal of method 1100 includes control signal Vctrl.

In operation 1104 of method 1100, a first oscillating signal (FOSC1) is output in response to the RF signal.

In some embodiments the first oscillating signal is output by buffer circuit 206.

In some embodiments, the first oscillating signal has the first oscillation frequency.

In some embodiments, the first oscillating signal of method 1100 includes oscillating signal FOSC1.

In operation 1106 of method 1100, a second oscillating signal is generated in response to the first oscillating signal.

In some embodiments, the second oscillating signal is generated by a frequency divider circuit. In some embodiments, the frequency divider circuit of method 1100 includes the frequency divider circuit 802 or 1000, or system 1200.

In some embodiments, the second oscillating signal includes oscillating signal FOSC2. In some embodiments, the second oscillating signal has a second oscillating frequency. In some embodiments, the second oscillating frequency is less than the first oscillating frequency. In some embodiments, the second oscillating frequency of method 1100 includes oscillating frequency F2.

In operation 1108 of method 1100, a first voltage is generated in response to the first oscillating signal or the second oscillating signal.

In some embodiments, the first voltage is generated by an FVC circuit. In some embodiments, the FVC circuit of method 1100 includes at least one of FVC circuit 208 or 500.

In some embodiments, the first voltage of method 1100 includes voltage VBIST.

In some embodiments, operation 1108 comprises at least one of operation 1108a, 1108b or 1108c.

In operation 1108a of method 1100, a first capacitor is charged in response to a first transistor turning on, and a second transistor, a third transistor and a fourth transistor turning off.

In some embodiments, the first capacitor of method 1100 includes capacitor C1.

In some embodiments, the first transistor of method 1100 includes PMOS transistor MP1.

In some embodiments, the second transistor of method 1100 includes NMOS transistor MN1.

In some embodiments, the third transistor of method 1100 includes NMOS transistor MN2.

In some embodiments, the fourth transistor of method 1100 includes NMOS transistor MN3.

In some embodiments, operation 1108a includes turning on the first transistor in response to the first oscillating signal or the second oscillating signal, and turning off the second transistor, the third transistor and the fourth transistor in response to a corresponding first phase, a second phase and a third phase.

In some embodiments, the first phase of method 1100 includes phase signal PHI2.

In some embodiments the second phase of method 1100 includes phase signal PHI1.

In some embodiments, the third phase of method 1100 includes phase signal PHI2B.

In operation 1108b of method 1100, a second capacitor is charged thereby setting the first voltage in response to the third transistor and the fourth transistor turning on, and the first transistor and the second transistor turning off.

In some embodiments, operation 1108b includes turning off the first transistor in response to the first oscillating signal or the second oscillating signal, turning off the second transistor in response to the first phase, and turning on the third transistor and the fourth transistor in response to the corresponding second phase and the third phase.

In operation 1108c of method 1100, the first capacitor is discharged in response to the second transistor turning on, and the first transistor, the third transistor and the fourth transistor turning off.

In some embodiments, operation 1108c includes turning off the first transistor in response to the first oscillating signal or the second oscillating signal, turning on the second transistor in response to the first phase, and turning off the third transistor and the fourth transistor in response to the corresponding second phase and the third phase.

In operation 1110 of method 1100, the first voltage is received from the FVC circuit.

In some embodiments, the first voltage is received by a first probe. In some embodiments, the first probe of method 1100 includes the set of probes 130.

In operation 1112 of method 1100, the first voltage is received from the first probe.

In some embodiments, the first voltage is received by the probe card 122.

In operation 1114 of method 1100, the first voltage is received from the probe card.

In some embodiments, the first voltage is received by the testing apparatus 120.

In operation 1116 of method 1100, a wafer acceptance test is performed on the first frequency in response to the first voltage.

In some embodiments, the wafer acceptance test is performed by the testing apparatus 120.

By operating method 1100, at least one of system 100 of FIG. 1, integrated circuit 200 of FIG. 2, VCO 300A of FIG. 3A, VCO 300B of FIG. 3A, FVC circuit 500 of FIG. 5, integrated circuit 800 of FIG. 8, frequency divider circuit 1000 of FIG. 10 or system 1200 of FIG. 12 operate to achieve the benefits discussed herein.

In some embodiments, one or more of the operations of method 1100 is not performed. Furthermore, various PMOS or NMOS transistors shown in FIGS. 3A-3B and 5 are of a particular dopant type (e.g., N-type or P-type) are for illustration purposes. Embodiments of the disclosure are not limited to a particular transistor type, and one or more of the PMOS or NMOS transistors shown in FIGS. 3A-3B and 5 can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments.

Selecting different numbers of transistors in FIGS. 3A-3B and 5 are within the scope of various embodiments. Selecting different numbers of individual elements in FIGS. 1-3B, 5, 6A-6B, 8, 10 and 12 is within the scope of various embodiments.

Other configurations of system 1100 are within the scope of the present disclosure.

FIG. 12 is a schematic view of a system 1200, in accordance with some embodiments. In some embodiments, system 1200 is an embodiment of at least testing apparatus 120 of FIG. 1, and similar detailed description is therefore omitted.

In some embodiments, system 1200 is an embodiment of at least one of testing system 112 of FIG. 1, VCO 202 of FIG. 2 or frequency divider circuit 802 of FIG. 8, and similar detailed description is therefore omitted.

In some embodiments, system 1200 is a digital VCO useable as VCO 202, and similar detailed description is therefore omitted.

In some embodiments, system 1200 is configured to control one or more of testing apparatus 120, testing system 112, VCO 202, the set of test lines 104, 204 or 804, the VCO 202, the VCO 300A, the VCO 300B, the FVC circuit 208, the FVC circuit 500 or the frequency divider circuit 802, and similar detailed description is therefore omitted.

In some embodiments, system 1200 is configured to generate one or more of control signal Vctrl, phase signal PHI1, phase signal PHI2, phase signal PHI2B or oscillating signal FOSC2.

In some embodiments, system 1200 is configured to perform one or more operations described herein including method 1100.

System 1200 includes a hardware processor 1202 and a non-transitory, computer readable storage medium 1204 (also referred to as “memory 1204” or “storage medium 1204”) encoded with, i.e., storing, the computer program code 1206, i.e., a set of executable instructions 1206.

Computer readable storage medium 1204 is configured for interfacing with at least one or more of testing apparatus 120, testing system 112, VCO 202, the set of test lines 104, 204 or 804, the VCO 202, the VCO 300A, the VCO 300B, the FVC circuit 208, the FVC circuit 500 or the frequency divider circuit 802, and similar detailed description is therefore omitted.

The processor 1202 is electrically coupled to the computer readable storage medium 1204 by a bus 1208. The processor 1202 is also electrically coupled to an I/O interface 1210 by bus 1208. A network interface 1212 is also electrically connected to the processor 1202 by bus 1208. Network interface 1212 is connected to a network 1214, so that processor 1202 and computer readable storage medium 1204 are capable of connecting to external elements by network 1214. The processor 1202 is configured to execute the computer program code 1206 (non-transitory instructions) encoded in the computer readable storage medium 1204 in order to cause system 1200 to be usable for performing a portion or all of the operations as described in at least method 1100. In some embodiments, network 1214 is not part of system 1200.

In some embodiments, the processor 1202 is a central processing unit (CPU), a multi-processor, a distributed processing read circuit, an application specific integrated circuit (ASIC), and/or a suitable processing unit.

In some embodiments, the computer readable storage medium 1204 is an electronic, magnetic, optical, electromagnetic, infrared, and/or a semiconductor read circuit (or apparatus or device). For example, the computer readable storage medium 1204 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1204 includes a compact disk-read only memory (CD-ROM), a compact disk-read/write (CD-R/W), and/or a digital video disc (DVD).

In some embodiments, the storage medium 1204 stores the computer program code 1206 configured to cause system 1200 to perform one or more operations of at least method 1100. In some embodiments, the storage medium 1204 also stores information used for performing at least method 1100 as well as information generated during performing at least method 1100, such as set of signals 1220, digital VCO 1222, frequency divider 1224 and user interface 1228, and/or a set of executable instructions to perform one or more operations of at least method 1100.

In some embodiments, the storage medium 1204 stores instructions (e.g., computer program code 1206) for interfacing with at least one of at least one or more of testing apparatus 120, testing system 112, VCO 202, the set of test lines 104, 204 or 804, the VCO 202, the VCO 300A, the VCO 300B, the FVC circuit 208, the FVC circuit 500 or the frequency divider circuit 802. The instructions (e.g., computer program code 1206) enable processor 1202 to generate instructions readable by at least one or more of testing apparatus 120, testing system 112, VCO 202, the set of test lines 104, 204 or 804, the VCO 202, the VCO 300A, the VCO 300B, the FVC circuit 208, the FVC circuit 500 or the frequency divider circuit 802 to effectively implement one or more operations of at least method 1100 during operation of system 100, integrated circuit 200, VCO 300A, VCO 300B, FVC circuit 500, integrated circuit 800 or frequency divider circuit 1000.

System 1200 includes I/O interface 1210. I/O interface 1210 is coupled to external circuitry. In some embodiments, I/O interface 1210 includes a keyboard, keypad, mouse, trackball, trackpad, and/or cursor direction keys for communicating information and commands to processor 1202.

System 1200 also includes network interface 1212 coupled to the processor 1202. Network interface 1212 allows system 1200 to communicate with network 1214, to which one or more other computer read circuits are connected. Network interface 1212 includes wireless network interfaces such as BLUETOOTH, WIFI, WIMAX, GPRS, or WCDMA; or wired network interface such as ETHERNET, USB, or IEEE-884. In some embodiments, at least method 1100 is implemented in two or more systems 1200, and information such as table, parity check matrix, set of data, set of check bits, syndrome, set of signals and user interface are exchanged between different systems 1200 by network 1214.

System 1200 is configured to receive information related to a set of data through I/O interface 1210 or network interface 1212. The information is stored in computer readable medium 1204 as set of signals 1220. In some embodiments, the set of signals includes at least one of control signal Vctrl, phase signal PHI1, phase signal PHI2, phase signal PHI2B or oscillating signal FOSC2.

System 1200 is configured to receive information related to a digital VCO through I/O interface 1210 or network interface 1212. The information is stored in computer readable medium 1204 as digital VCO 1222.

System 1200 is configured to receive information related to a frequency divider through I/O interface 1210 or network interface 1212. The information is then stored in computer readable medium 1204 as frequency divider 1224.

System 1200 is configured to receive information related to a user interface through I/O interface 1210 or network interface 1212. The information is stored in computer readable medium 1204 as user interface 1228.

Other configurations of system 1200 are within the scope of the present disclosure.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

One aspect of this description relates to a system. In some embodiments, the system includes a first circuit, a converter circuit and a testing system. In some embodiments, the first circuit is configured to generate a radio frequency (RF) signal, the RF signal having a first oscillation frequency. In some embodiments, the converter circuit is coupled to the first circuit, configured to receive the RF signal, and to convert the RF signal into a first voltage representative of a value of the first oscillation frequency. In some embodiments, the first voltage is a direct current voltage. In some embodiments, the testing system is coupled to the converter circuit, and configured to receive the first voltage, and to perform a wafer acceptance test (WAT) on the first oscillation frequency in response to the first voltage.

Another aspect of this description relates to a system. In some embodiments, the system includes a wafer. In some embodiments, the system further includes a test structure on the wafer, and configured to generate a radio frequency (RF) signal, the RF signal having a first oscillation frequency. In some embodiments, the system further includes a set of test lines coupled to the test structure. In some embodiments, the set of test lines includes a converter circuit coupled to the test structure, and configured to receive the RF signal, and to convert the RF signal into a first voltage representative of a value of the first oscillation frequency, the first voltage being a direct current voltage. In some embodiments, the system further includes a testing system coupled to the converter circuit, and configured to receive the first voltage, and to perform a wafer acceptance test (WAT) on the first oscillation frequency in response to the first voltage.

Still another aspect of this description relates to a method of operating a system. In some embodiments, the method includes generating, by a first circuit, a radio frequency (RF) signal in response to a first control signal, the RF signal having a first oscillation frequency. In some embodiments, the method further includes outputting, by a buffer circuit, a first oscillating signal in response to the RF signal, the first oscillating signal having the first oscillation frequency. In some embodiments, the method further includes generating, by a frequency divider circuit, a second oscillating signal in response to the first oscillating signal, the second oscillating signal having a second oscillating frequency less than the first oscillating frequency. In some embodiments, the method further includes generating, by a frequency-to-voltage converter (FVC) circuit, a first voltage in response to the first oscillating signal or the second oscillating signal. In some embodiments, the method further includes receiving, by a first probe, the first voltage from the FVC circuit. In some embodiments, the method further includes receiving, by a probe card, the first voltage from the first probe. In some embodiments, the method further includes receiving, by a testing apparatus, the first voltage from the probe card. In some embodiments, the method further includes performing, by the testing apparatus, a wafer acceptance test (WAT) on the first oscillation frequency in response to the first voltage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a first circuit configured to generate a radio frequency (RF) signal, the RF signal having a first oscillation frequency;
a converter circuit coupled to the first circuit, configured to receive the RF signal, and to convert the RF signal into a first voltage representative of a value of the first oscillation frequency, the first voltage being a direct current voltage; and
a testing system coupled to the converter circuit, and configured to receive the first voltage, and to perform a wafer acceptance test (WAT) on the first oscillation frequency in response to the first voltage.

2. The system of claim 1, wherein the first circuit comprises:
a voltage controlled oscillator (VCO) configured to receive a first control signal, and to generate the RF signal in response to the first control signal.

3. The system of claim 2, wherein the converter circuit comprises:
a buffer circuit coupled to the VCO, and configured to receive the RF signal, and to output a first oscillating signal, the first oscillating signal having the first oscillation frequency; and
a frequency-to-voltage converter (FVC) circuit coupled to the buffer circuit, and configured to receive the first oscillating signal, and to generate the first voltage in response to the first oscillating signal.

4. The system of claim 3, wherein the FVC circuit comprises:
a first current source coupled between a first voltage supply and a first node, the first current source configured to generate a first current;
a first p-type transistor including a first terminal of the first p-type transistor configured to receive the first oscillating signal, a second terminal of the first p-type transistor is coupled to the first node and the first current source, and a third terminal of the first p-type transistor is coupled to a second node; and
a first n-type transistor including a first terminal of the first n-type transistor configured to receive the first oscillating signal and being coupled to the first terminal of the first p-type transistor, a second terminal of the first n-type transistor is coupled to a reference voltage supply, and a third terminal of the first n-type transistor is coupled to the third terminal of the first p-type transistor and the first current source.

5. The system of claim 4, wherein the FVC circuit further comprises:
a second n-type transistor including a first terminal of the second n-type transistor configured to receive a first phase, a second terminal of the second n-type transistor is coupled to the reference voltage supply, and a third terminal of the second n-type transistor is coupled to the third terminal of the first p-type transistor and the second node; and
a first capacitor coupled between the reference voltage supply and the second node.

6. The system of claim 5, wherein the FVC circuit further comprises:
a third n-type transistor including a first terminal of the third n-type transistor configured to receive a second phase, a second terminal of the third n-type transistor is coupled to the second node and the second terminal of the second n-type transistor, and a third terminal of the third n-type transistor is coupled to a third node;
a fourth n-type transistor including a first terminal of the fourth n-type transistor configured to receive a third phase, a second terminal of the fourth n-type transistor is coupled to the third node and the third terminal of the third n-type transistor, and a third terminal of the fourth n-type transistor is coupled to an output node; and
a second capacitor coupled between the reference voltage supply and the output node.

7. The system of claim 2, wherein the VCO comprises:
a first variable resistor coupled between a first voltage supply and a first node;
a first inductor including a first terminal of the first inductor coupled to the first variable resistor and the first node, a second terminal of the first inductor is coupled to a second node, and a third terminal of the first inductor is coupled to a third node;
a first varactor including a first terminal of the first varactor coupled to the second node and the second terminal of the first inductor, and a second terminal of the first varactor coupled to a first input node; and
a second varactor including a first terminal of the second varactor coupled to the third node and the third terminal of the first inductor, and a second terminal of the second varactor coupled to the first input node and the second terminal of the first varactor,
wherein the first input node is configured to receive the first control signal.

8. The system of claim 7, wherein the VCO further comprises:
a first n-type transistor including a first terminal, a second terminal, and a third terminal;
a second n-type transistor including a first terminal, a second terminal, and a third terminal;
wherein each of the first terminal of the first n-type transistor, the third terminal of the second n-type transistor, the first terminal of the second varactor, the third node and the third terminal of the first inductor are coupled together, and correspond to a first output terminal of the VCO;
wherein each of the first terminal of the second n-type transistor, the third terminal of the first n-type transistor, the first terminal of the first varactor, the second node and the second terminal of the first inductor are coupled together, and correspond to a second output terminal of the VCO; and
wherein each of the second terminal of the first n-type transistor and the second terminal of the second n-type transistor is coupled to a reference voltage supply.

9. The system of claim 8, wherein
the first varactor comprises:
a first p-type transistor including a first terminal, a second terminal, and a third terminal; and
the second varactor comprises:
a second p-type transistor including a first terminal, a second terminal, and a third terminal;
wherein the first terminal of the first p-type transistor is coupled to the first terminal of the second n-type transistor, the third terminal of the first n-type transistor, the second node and the second terminal of the first inductor;
the first terminal of the second p-type transistor is coupled to the first terminal of the first n-type transistor, the third terminal of the second n-type transistor, the third node and the third terminal of the first inductor; and
each of the second terminal of the first p-type transistor, the third terminal of the first p-type transistor, the second terminal of the second p-type transistor, the third terminal of the second p-type transistor and the first input node are coupled together.

10. A system comprising:
a wafer;
a test structure on the wafer, and configured to generate a radio frequency (RF) signal, the RF signal having a first oscillation frequency;
a set of test lines coupled to the test structure, the set of test lines comprising:
a converter circuit coupled to the test structure, and configured to receive the RF signal, and to convert the RF signal into a first voltage representative of a value of the first oscillation frequency, the first voltage being a direct current voltage; and
a testing system coupled to the converter circuit, and configured to receive the first voltage, and to perform a wafer acceptance test (WAT) on the first oscillation frequency in response to the first voltage.

11. The system of claim 10, wherein the testing system comprises:
a probe coupled to the set of test lines, and configured to receive the first voltage from the set of test lines;
a probe card coupled to the probe, and configured to receive the first voltage from the probe; and
a testing apparatus coupled to the probe card, and configured to receive the first voltage from the probe card, and to measure the first voltage thereby performing the WAT on the first oscillation frequency in response to the first voltage.

12. The system of claim 10, wherein the test structure comprises:
a voltage controlled oscillator (VCO) configured to receive a first control signal, and to generate the RF signal in response to the first control signal.

13. The system of claim 12, wherein the converter circuit comprises:
a buffer circuit coupled to the VCO, and configured to receive the RF signal, and to output a first oscillating signal, the first oscillating signal having the first oscillation frequency;
a frequency divider circuit coupled to the buffer circuit, and configured to receive the first oscillating signal and to generate a second oscillating signal in response to the first oscillating signal, the second oscillating signal having a second oscillating frequency less than the first oscillating frequency; and
a frequency-to-voltage converter (FVC) circuit coupled to the frequency divider circuit, and configured to receive the second oscillating signal, and to generate the first voltage in response to the second oscillating signal.

14. The system of claim 13, wherein the FVC circuit comprises:
a first current source coupled between a first voltage supply and a first node, the first current source configured to generate a first current;
a first p-type transistor including a first terminal of the first p-type transistor configured to receive the second oscillating signal, a second terminal of the first p-type transistor is coupled to the first node and the first current source, and a third terminal of the first p-type transistor is coupled to a second node; and
a first n-type transistor including a first terminal of the first n-type transistor configured to receive the second oscillating signal and being coupled to the first terminal of the first p-type transistor, a second terminal of the first n-type transistor is coupled to a reference voltage supply, and a third terminal of the first n-type transistor is coupled to the third terminal of the first p-type transistor and the first current source.

15. The system of claim 14, wherein the FVC circuit further comprises:
a second n-type transistor including a first terminal of the second n-type transistor configured to receive a first phase, a second terminal of the second n-type transistor is coupled to the reference voltage supply, and a third terminal of the second n-type transistor is coupled to the third terminal of the first p-type transistor and the second node; and
a first capacitor coupled between the reference voltage supply and the second node.

16. The system of claim 15, wherein the FVC circuit further comprises:
a third n-type transistor including a first terminal of the third n-type transistor configured to receive a second phase, a second terminal of the third n-type transistor is coupled to the second node and the second terminal of the second n-type transistor, and a third terminal of the third n-type transistor is coupled to a third node;
a fourth n-type transistor including a first terminal of the fourth n-type transistor configured to receive a third phase, a second terminal of the fourth n-type transistor is coupled to the third node and the third terminal of the third n-type transistor, and a third terminal of the fourth n-type transistor is coupled to an output node; and
a second capacitor coupled between the reference voltage supply and the output node.

17. The system of claim 12, wherein the VCO comprises:
a first variable resistor coupled between a first voltage supply and a first node;
a first inductor including a first terminal of the first inductor coupled to the first variable resistor and the first node, a second terminal of the first inductor is coupled to a second node, and a third terminal of the first inductor is coupled to a third node;
a first varactor including a first terminal of the first varactor coupled to the second node and the second terminal of the first inductor, and a second terminal of the first varactor coupled to a first input node; and
a second varactor including a first terminal of the second varactor coupled to the third node and the third terminal of the first inductor, and a second terminal of the second varactor coupled to the first input node and the second terminal of the first varactor,
wherein the first input node is configured to receive the first control signal.

18. The system of claim 17, wherein the VCO further comprises:
a first n-type transistor including a first terminal, a second terminal, and a third terminal;
a second n-type transistor including a first terminal, a second terminal, and a third terminal;
wherein each of the first terminal of the first n-type transistor, the third terminal of the second n-type transistor, the first terminal of the second varactor, the third node and the third terminal of the first inductor are coupled together, and correspond to a first output terminal of the VCO;
wherein each of the first terminal of the second n-type transistor, the third terminal of the first n-type transistor, the first terminal of the first varactor, the second node and the second terminal of the first inductor are coupled together, and correspond to a second output terminal of the VCO; and
wherein each of the second terminal of the first n-type transistor and the second terminal of the second n-type transistor is coupled to a reference voltage supply.

19. The system of claim 18, wherein
the first varactor comprises:
a first p-type transistor including a first terminal, a second terminal, and a third terminal; and
the second varactor comprises:
a second p-type transistor including a first terminal, a second terminal, and a third terminal;
wherein the first terminal of the first p-type transistor is coupled to the first terminal of the second n-type transistor, the third terminal of the first n-type transistor, the second node and the second terminal of the first inductor;
the first terminal of the second p-type transistor is coupled to the first terminal of the first n-type transistor, the third terminal of the second n-type transistor, the third node and the third terminal of the first inductor; and
each of the second terminal of the first p-type transistor, the third terminal of the first p-type transistor, the second terminal of the second p-type transistor, the third terminal of the second p-type transistor and the first input node are coupled together.

20. A method of operating a system, the method comprising:
generating, by a first circuit, a radio frequency (RF) signal in response to a first control signal, the RF signal having a first oscillation frequency;
outputting, by a buffer circuit, a first oscillating signal in response to the RF signal, the first oscillating signal having the first oscillation frequency;
generating, by a frequency divider circuit, a second oscillating signal in response to the first oscillating signal, the second oscillating signal having a second oscillating frequency less than the first oscillating frequency;
generating, by a frequency-to-voltage converter (FVC) circuit, a first voltage in response to the first oscillating signal or the second oscillating signal;
receiving, by a first probe, the first voltage from the FVC circuit;
receiving, by a probe card, the first voltage from the first probe;
receiving, by a testing apparatus, the first voltage from the probe card; and
performing, by the testing apparatus, a wafer acceptance test (WAT) on the first oscillation frequency in response to the first voltage.
